(19) United States
(12) Patent Application Publication
(10) Pub. No.: US 2016/0146918 A1
(43) Pub. Date: May 26, 2016

(54) CORRECTED MAGNETIC RESONANCE IMAGING USING COIL SENSITIVITIES

(71) Applicant: KONINKLIJKE PHILIPS N.V., Eindhoven (NL)

(72) Inventors: ZHAOLIN CHEN, EINDHOVEN (NL); ADRIANUS JOSEPH WILLIBRORDUS DUIJNDAM, EINDHOVEN (NL); GERRIT HENDRIK VAN IJPEREN, EINDHOVEN (NL)

(21) Appl. No.: 14/903,616

(22) PCT Filed: Jul. 1, 2014
(86) PCT No.: PCT/EP2014/063889

§ 371 Date: Jan. 8, 2016

(30) Foreign Application Priority Data
Jul. 11, 2013 (EP) 13176014.2

(51) Int. Cl. G01R 33/58; G01R 33/56; G01R 33/565

(52) U.S. Cl. CPC G01R 33/583; G01R 33/5659; G01R 33/5608

(57) ABSTRACT

The invention provides for a medical apparatus (300, 400) for generating a corrected magnetic resonance image (326, 502, 600, 700). The medical apparatus comprises a processor (308) for executing instructions, wherein execution of the instructions causes the processor to: receive (100) a set of N magnetic resonance images (320), wherein each of the set of N magnetic resonance images corresponds to one of N coil elements (426) of a magnetic resonance imaging coil (424); receive (102) a set of coil sensitivities (322) for each of the N coil elements; determine (104) for each of the N coil elements a coil sensitivity calibration (324) for each of the pixels; calculate (106) a value for each pixel of the corrected magnetic resonance image by dividing a first summation comprising the value of the pixel in each of the set of N magnetic resonance images by a second summation comprising the coil sensitivity calibration for the pixel in each of the set of coil sensitivities, wherein the first summation and the second summation are real valued.

### TECHNICAL FIELD

The invention relates to magnetic resonance imaging, in particular to the correction of inhomogeneities in the image.

### BACKGROUND OF THE INVENTION

A large static magnetic field is used by Magnetic Resonance Imaging (MRI) scanners to align the nuclear spins of atoms as part of the procedure for producing images within the body of a patient. This large static magnetic field is referred to as the B0 field. During an MRI scan, Radio Frequency (RF) pulses generated by a transmitter coil cause perturbations to the local magnetic field, and RF signals emitted by the nuclear spins are detected by a receiver coil. These RF signals are used to construct the MRI images. These coils can also be referred to as antennas. Further, the transmitter and receiver coils can also be integrated into a single transceiver coil that performs both functions. It is understood that the use of the term transceiver coil also refers to systems where separate transmitter and receiver coils are used. The transmitted RF field is referred to as the B1 field. MRI scanners are able to construct images of either slices or volumes. A slice is a thin volume that is only one voxel thick. A voxel is a small volume over which the MRI signal is averaged, and represents the resolution of the MRI image. A voxel may also be referred to as a pixel herein.

A surface coil is a type of receiver coil that is placed directly on or over the region of interest. The use of a surface coils offers increased magnetic sensitivity, however surface coils have a spatially dependent sensitivity which can lead to inhomogeneities in the resulting magnetic resonance image.

U.S. Pat. No. 5,600,244 (hereafter '244 patent) describes a method of reducing the inhomogeneities in magnetic resonance images acquired with surface coils.

The PROPELLER technique of acquiring magnetic resonance images is detailed in the journal article Pipe et. al., “Motion Correction With PROPELLER MRI: Application to Head Motion and Free-Breathing Cardiac Imaging,” Magn. Res. Med., volume 42, pages 963-969 (1999), hereafter Pipe et. al. Further, the paper by E.G. Larsson et al. ‘SNR-optimality of sum-of squares reconstruction for phased array magnetic resonance imaging’ in JMR 163(2003)121-123 mentions that the optimal estimate of the object density reconstructed from the measured signals is obtained by maximum-ratio combining in which the complex valued signals and coil sensitiviteis are used. Further, this paper shows that the maximum ration combining has asymotitically the signal-to-noise ration of the sum-of-squares solution at strong signals.

### SUMMARY OF THE INVENTION

The invention provides for a medical apparatus, a computer program product and a method of magnetic resonance imaging in the independent claims. Embodiments are given in the dependent claims.

As will be appreciated by one skilled in the art, aspects of the present invention may be embodied as an apparatus, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer executable code embodied thereon.

Any combination of one or more computer readable medium(s) may be utilized. The computer readable medium may be a computer readable signal medium or a computer readable storage medium. A ‘computer-readable storage medium’ as used herein encompasses any tangible storage medium which may store instructions which are executable by a processor of a computing device. The computer-readable storage medium may be referred to as a computer-readable non-transitory storage medium. The computer-readable storage medium may also be referred to as a tangible computer readable medium. In some embodiments, a computer-readable storage medium may also be able to store data which is able to be accessed by the processor of the computing device. Examples of computer-readable storage media include, but are not limited to: a floppy disk, a magnetic hard disk drive, a solid state hard disk, flash memory, a USB thumb drive, Random Access Memory (RAM), Read Only Memory (ROM), an optical disk, a magneto-optical disk, and the register file of the processor. Examples of optical disks include Compact Disks (CD) and Digital Versatile Disks (DVD), for example CD-ROM, CD-RW, CD-R, DVD-ROM, DVD-RW, or DVD-R disks. The term computer readable-storage medium also refers to various types of recording media capable of being accessed by the computer device via a network or communication link. For example a data may be retrieved over a modem, over the internet, or over a local area network. Computer executable code embodied on a computer readable medium may be transmitted using any appropriate medium, including but not limited to wireless, wireline, optical fiber cable, RF, etc., or any suitable combination of the foregoing.

A computer readable signal medium may include a propagated data signal with computer executable code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

‘Computer memory’ or ‘memory’ is an example of a computer-readable storage medium. Computer memory is any memory which is directly accessible to a processor. ‘Computer storage’ or ‘storage’ is a further example of a computer-readable storage medium. Computer storage is any non-volatile computer-readable storage medium. In some embodiments computer storage may also be computer memory or vice versa.

A ‘processor’ as used herein encompasses an electronic component which is able to execute a program or machine executable instruction or computer executable code. References to the computing device comprising “a processor” should be interpreted as possibly containing more than one processor or processing core. The processor may for instance be a multi-core processor. A processor may also refer to a collection of processors within a single computer system or distributed amongst multiple computer systems. The term computing device should also be interpreted to possibly refer to a collection or network of computing devices each comprising a processor or processors. The computer executable code may be executed by multiple processors that may be within the same computing device or which may even be distributed across multiple computing devices.

Computer executable code may comprise machine executable instructions or a program which causes a processor to perform an aspect of the present invention. Computer executable code for carrying out operations for aspects of the present invention may be written in any combination of one or more programming languages, including an object oriented programming language such as Java, Smalltalk, C++ or the like and conventional procedural programming languages, such as the “C” programming language or similar programming languages and compiled into machine executable instructions. In some instances the computer executable code may be in the form of a high level language or in a pre-compiled form and be used in conjunction with an interpreter which generates the machine executable instructions on the fly.

The computer executable code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described with reference to flowchart illustrations and/or block diagrams of methods, apparatus (systems) and computer program products according to embodiments of the invention. It will be understood that each block or a portion of the blocks of the flowchart, illustrations, and/or block diagrams, can be implemented by computer program instructions in form of computer executable code when applicable. It is further under stood that, when not mutually exclusive, combinations of blocks in different flowcharts, illustrations, and/or block diagrams may be combined. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

A ‘user interface’ as used herein is an interface which allows a user or operator to interact with a computer or computer system. A ‘user interface’ may also be referred to as a ‘human interface device.’ A user interface may provide information or data to the operator and/or receive information or data from the operator. A user interface may enable input from an operator to be received by the computer and may provide output to the user from the computer. In other words, the user interface may allow an operator to control or manipulate a computer and the interface may allow the computer indicate the effects of the operator's control or manipulation. The display of data or information on a display or a graphical user interface is an example of providing information to an operator. The receiving of data through a keyboard, mouse, trackball, touchpad, pointing stick, graphics tablet, joystick, gamepad, webcam, headset, gear sticks, steering wheel, pedals, wired glove, dance pad, remote control, and accelerometer are all examples of user interface components which enable the receiving of information or data from an operator.

A ‘hardware interface’ as used herein encompasses an interface which enables the processor of a computer system to interact with and/or control an external computing device and/or apparatus. A hardware interface may allow a processor to send control signals or instructions to an external computing device and/or apparatus. A hardware interface may also enable a processor to exchange data with an external computing device and/or apparatus. Examples of a hardware interface include, but are not limited to: a universal serial bus, IEEE 1394 port, parallel port, IEEE 1284 port, serial port, RS-232 port, IEEE-488 port, Bluetooth connection, Wireless local area network connection, TCP/IP connection, Ethernet connection, control voltage interface, MIDI interface, analog input interface, and digital input interface.

A ‘display’ or ‘display device’ as used herein encompasses an output device or a user interface adapted for displaying images or data. A display may output visual, audio, and or tactile data. Examples of a display include, but are not limited to: a computer monitor, a television screen, a touch screen, tactile electronic display, Braille screen, Cathode ray tube (CRT), Storage tube, Bi-stable display, Electronic paper, Vector display, Flat panel display, Vacuum fluorescent display (VF), Light-emitting diode (LED) displays, Electroluminescent display (ELD), Plasma display panels (PDP), Liquid crystal display (LCD), Organic light-emitting diode displays (OLED), a projector, and Head-mounted display.

Magnetic Resonance (MR) data is defined herein as being the recorded measurements of radio frequency signals emitted by atomic spins by the antenna of a Magnetic resonance apparatus during a magnetic resonance imaging scan. Magnetic resonance data is an example of medical image data. A Magnetic Resonance Imaging (MRI) image is defined herein as being the reconstructed two or three dimensional visualization of anatomic data contained within the magnetic resonance imaging data. This visualization can be performed using a computer.

In one aspect the invention provides for a medical apparatus for generating a corrected magnetic resonance image comprising pixels. The pixels may also be referred to alternatively as voxels. The medical apparatus comprises a memory for storing machine-executable instructions. The medical apparatus further comprises a processor for executing the machine-executable instructions. Execution of the machine-executable instructions causes the processor to receive a set of N magnetic resonance images. N is a positive integer greater than or equal to 1. Alternatively, N may be a positive integer that is greater than or equal to 2. Each of the set N magnetic resonance images corresponds to one of N coil elements of a magnetic resonance imaging coil. The magnetic resonance imaging coil may be a surface coil. The magnetic resonance imaging coil may be a multi-element magnetic resonance imaging coil. Each of the N images then corresponds to one of the N coil elements. In other words the N magnetic resonance images were each acquired from one of the N coil elements. Each of the set of N magnetic resonance images comprises the same number of pixels as the corrected magnetic resonance image.

Execution of the machine-executable instructions further causes the processor to receive a set of coil sensitivities for each of the N coil elements. The coil sensitivities may be a complex value or they may also be a magnitude in which case the magnitude would be a real positive valued value. In this particular step the coil sensitivities are known a priori. They may have been previously measured. For instance one of the coil elements may be selected as a reference for the other coil elements or a different magnetic resonance imaging coil may be used to acquire a baseline measurement. For instance a so called body coil may be used.

Execution of the machine-executable instructions further cause the processor to determine for each of the N coil elements a coil sensitivity calibration for each of the pixels. Often times when coil sensitivities are acquired a low resolution scan will be acquired with a body coil and then relatively low resolution images for each of the coil elements of a multi-element imaging coil will be acquired. A later acquired clinical image such as the corrected magnetic resonance image may have a finer resolution for the pixels or voxels than was used during the determination of the coil sensitivities. In this step a coil sensitivity calibration refers to the determination of the coil sensitivity for each particular pixel. This may involve interpolating the value between different coil sensitivities taken at a lower resolution or assigning particular coil sensitivity to a particular pixel for the individual coil element. For instance the pixels within one of the images could be divided in different regions and each of these regions is assigned particular coil sensitivity.

Execution of the machine-executable instructions further cause the processor to calculate a value for each pixel of the pixels by dividing a first summation comprising the modulus value of the pixels in each of the set of N magnetic resonance images by a second summation comprising the modulus of the coil sensitivity for the pixel in each of the set of coil sensitivities. The first summation and the second summation are real valued. This embodiment may be beneficial because the first summation and the second summation are real valued. This implies that the coil sensitivity or the value of a pixel in a particular image does not need to be complex valued. This provides for a broad means of equalizing a magnetic resonance image constructed from a set of N magnetic resonance images. This may be useful for reducing the inhomogeneity of an image acquired using surface coils with multiple elements. That is, in the corrected image the pixel values are corrected for inhomogeneities due to the spatial variations of the coil sensitivities.

In another embodiment the first summation is a summation of the magnitude of the coil sensitivity for the pixel in each of the set of coil sensitivities times the magnitude of the pixel in each of the set of N magnetic resonance images. The second summation is a summation of the square of the magnitude of the coil sensitivity for the pixel. This embodiment may be beneficial because it provides a method of reducing inhomogeneity when using multiple coil elements when an MRI imaging technique with local phase correction is used. This is because the calculation does not depend on the values being complex valued.

In another embodiment the first summation divided by the second summation is algebraically equivalent to:

$${\sum }_{i = 1}^{N} \vert {S}_{i} \vert \vert {m}_{i} \vert / ( {\sum }_{i = 1}^{N} ( {\vert {S}_{i} \vert}^{2} ) + {R}^{- 1} )$$

$$or$$

$${\sum }_{i = 1}^{N} \vert {S}_{i} \vert \vert {m}_{i} \vert / ( {\sum }_{i = 1}^{N} {\vert {S}_{i} \vert}^{2} )$$

$$or$$

$${\sum }_{i = 1}^{N} \vert {S}_{i} \vert \vert {m}_{i} \vert / ( ( {\sum }_{i = 1}^{N} {\vert {S}_{i} \vert}^{2} ) + {R}^{- 1} )$$

$$or$$

$${\sum }_{i = 1}^{N} \vert {S}_{i} \vert \vert {m}_{i} \vert / ( {\sum }_{i = 1}^{N} {\vert {S}_{i} \vert}^{2} )$$

In these equations: i is an index variable, mᵢ is the value of the pixel in the ith member of the set of N magnetic resonance images, Sᵢ is the coil sensitivity for pixel of the ith member the set of coil sensitivities, and R is a regularization parameter.

The regularization parameter R is used to reduce the effect of noise for pixels which are associated with the region in the examination zone which has only weak or no magnetic resonance signals. The value of the regularization parameter is chosen such that its effect on the overall value is known only for pixels in which only a small MR signal or even no MR signal can arise because the nuclear magnetization distribution or proton density within a subject. For instance the value of R may be chosen such that when examining the corrected magnetic resonance image it is not apparent that there is a value of R that was used.

However, outside of the subject there may be an area in free space which was imaged. The regularization parameter may also be chosen to be a small number to prevent a divide by 0 error. The regularization parameter may also be equivalent to either regularization parameters r₁ or r₂ as defined and used in U.S. Pat. No. 6,500,244. See lines 40 to 46 in Col. 6 of U.S. Pat. No. 6,500,244 for r₁. See lines 5 to 25 in Col. 7 of U.S. Pat. No. 6,500,244 for r₂.

In another embodiment the first summation is the summation of the square of the magnitude of the value of the pixel in each of the set of N magnetic resonance images. The second summation is the square root of the summation of the square of the magnitude of the complex coil sensitivity for the pixel.

In another embodiment the first summation divided by the second summation is alternatively written or is algebraically equivalent to:

$$\sqrt{{\sum }_{i = 1}^{N} {\vert {m}_{i} \vert}^{2}} / \sqrt{( {\sum }_{i = 1}^{N} {\vert {S}_{i} \vert}^{2} ) + {R}^{- 1}}$$

$$or$$

$$\sqrt{{\sum }_{i = 1}^{N} {\vert {m}_{i} \vert}^{2}} / \sqrt{{\sum }_{i = 1}^{N} {\vert {S}_{i} \vert}^{2}}$$

In these equations: i is an index variable, mᵢ is the value of the pixel in the ith member of the set of N magnetic resonance images, Sᵢ is the coil sensitivity for pixel of the ith member the set of coil sensitivities, and R is a regularization parameter. The regularization parameter R was defined above.

In another embodiment the pixels in each of the set of N magnetic resonance images are real valued. This embodiment may be beneficial because it enables the reducing of inhomogeneity of surface coils when the pixels in the N magnetic resonance images are real valued. That is, the effect of the spatial variations of the coil sensitivites of the surface coils is corrected for in the corrected image. For instance the method disclosed in U.S. Pat. No. 5,600,244 will not work when the pixels in each of the set of N magnetic resonance images are real valued. The method in this patent relies on the image having complex values.

In another embodiment the medical apparatus comprises a magnetic resonance imaging system. The magnetic resonance imaging system further comprises a radio-frequency system operable for acquiring magnetic resonance data with the magnetic resonance imaging coil. Execution of the instructions further causes the processor to acquire imaging magnetic resonance data using the radio-frequency system and the magnetic resonance imaging coil. Execution of the instructions further causes the processor to reconstruct the imaging magnetic resonance data into the set of N magnetic resonance images. In this case the set of N magnetic resonance images has been received by acquiring them using the magnetic resonance imaging system. The magnetic resonance imaging system may comprise the multi-element or single element magnetic resonance imaging coil.

In another embodiment the magnetic resonance imaging system further comprises a uniform body coil. The radio-frequency system is operable for acquiring reference magnetic resonance data using the uniform body coil. A uniform body coil as used herein encompasses a magnetic resonance imaging antenna or coil operable for acquiring the magnetic resonance data from a relatively large area. For instance this is in contrast to a surface coil. The magnetic resonance imaging coil may be a surface coil. The individual elements of the magnetic resonance imaging coil are able to acquire magnetic resonance data within their immediate vicinity. The uniform body coil is not able to acquire the detail of data but it is able to acquire image data uniformly. The uniform body coil may therefore be used as a reference to compare the individual elements of the magnetic resonance coil against.

Execution of the machine-readable instructions further cause the processor to acquire the reference magnetic resonance data using the radio-frequency system and the uniform body coil. Execution of the instructions further cause the processor to acquire calibration magnetic resonance data using the radio-frequency system and the magnetic resonance imaging coil. Execution of the instructions further causes the processor to reconstruct a reference magnetic resonance image using the reference magnetic resonance data. Execution of the instructions further cause the processor to reconstruct a set of N calibration magnetic resonance images using the calibration magnetic resonance data.

Execution of the instructions further cause the processor to calculate the set of coil sensitivities using the set of m calibration magnetic resonance images and the reference magnetic resonance image.

The calculation of the coil sensitivities is commonly known in the art. In this embodiment it is specified that the receiving of the set of coil sensitivities is performed by measuring the reference magnetic resonance data and the calibration magnetic resonance data with the magnetic resonance imaging system.

In another embodiment execution of the machine-readable instructions further cause the processor to acquire the imaging magnetic resonance data using a PROPELLER technique. The magnetic resonance data is reconstructed into the set of N magnetic resonance images using the PROPELLER technique. This embodiment may be beneficial because the steps performed by the processor of the medical apparatus provide for a means of making the magnetic resonance image reconstructed using the PROPELLER technique more uniform.

In another embodiment the PROPELLER technique uses phase correction to remove a low-frequency spatially varying phase error in image space. This embodiment may be beneficial because the phase correction used in the PROPELLER technique removes phase data from the set of N images. As such the method disclosed in U.S. Pat. No. 5,600,244 will not work with a PROPELLER technique that uses phase correction to remove a low-frequency spatially varying phase error in image space.

In another embodiment the magnetic resonance data is acquired using a non-Cartesian magnetic resonance imaging technique. A non-Cartesian magnetic resonance imaging technique refers to the selection of sample points in k-space. For instance this may be the fact that the k-space is sampled radially or in a non-rectilinear manner.

In another embodiment execution of the instructions further causes the processor to receive the coil sensitivities when the coil sensitivities are acquired in partial k-space. When the coil sensitivities are acquired in partial k-space this is equivalent to saying that the sensitivities are only magnitudes. When the sensitivities are only magnitudes they do not have complex values and therefore cannot be used in the technique disclosed in U.S. Pat. No. 5,600,244.

In another aspect the invention provides for a computer program product comprising machine-executable instructions for execution by a processor controlling the medical instrument. Execution of the machine-executable instructions causes the processor to receive a set of N magnetic resonance images. N is a positive integer greater than or equal to 1. Alternatively N may be a positive integer greater than or equal to 2. Each of the set of N magnetic resonance images corresponds to one of N coil elements of a magnetic resonance imaging coil. Each of the set of N magnetic resonance images comprises the same number of pixels as the corrected magnetic resonance image. Execution of the machine-executable instructions further causes the processor to receive a set of coil sensitivities for each of the N coil elements.

Execution of the instructions further causes the processor to determine for each of the N coil elements a coil sensitivity calibration for each of the pixels. Execution of the instructions further cause the processor to calculate a value for each pixel of the pixels by dividing a first summation comprising the value of the pixel in each of the set of N magnetic resonance images by a second summation comprising the coil sensitivity for the pixel in each of the set of coil sensitivities. The first summation and the second summation are real valued.

In another aspect the invention provides for a method of using or generating a corrected magnetic resonance image. The method comprises the step of receiving a set of N magnetic resonance images. N is a positive integer greater than or equal to 1. Alternatively N is a positive integer greater than or equal to 2. Each of the set of N magnetic resonance images corresponds to one of N coil elements of a magnetic resonance imaging coil. Each of the set N magnetic resonance images comprises the same number of pixels as the corrected magnetic resonance image. The method further comprises the step of receiving the set of coil sensitivities for each of the N coil elements. The method further comprises the step of determining for each of the N coil elements a coil sensitivity calibration for each of the pixels. The method further comprises calculating a value for each pixel of the pixels by dividing a first summation comprising the value of the pixel in each of the N magnetic resonance images by a second summation comprising the coil sensitivity for the pixel in each of the set of coil sensitivities. The first summation and the second summation are real valued. The generation or creation of the corrected magnetic resonance image is performed by calculating the value for each pixel of this image.

In another embodiment the method is performed using the magnetic resonance imaging system which comprises a radio-frequency system operable for acquiring magnetic resonance data with the magnetic resonance imaging coil. The magnetic resonance imaging system further comprises a uniform body coil. The radio-frequency system is operable for acquiring reference magnetic resonance data using the uniform body coil. The method further comprises the step of acquiring the reference magnetic resonance data using the radio-frequency system and the uniform body coil. The method further comprises the step of reconstructing a reference magnetic resonance image using the reference magnetic resonance data.

The method further comprises the step of acquiring the calibration magnetic resonance data using the radio-frequency system and the magnetic resonance imaging coil. The method further comprises the step of reconstructing the set of N calibration magnetic resonance images using the calibration magnetic resonance data. The method further comprises the step of calculating the set of coil sensitivities using the set of N calibration magnetic resonance images and the reference magnetic resonance image. The method further comprises the step of acquiring image magnetic resonance data using the radio-frequency system and the magnetic resonance imaging coil. The method further comprises the step of reconstructing the imaging magnetic resonance data into the set of N magnetic resonance images.

It is understood that one or more of the aforementioned embodiments of the invention may be combined as long as the combined embodiments are not mutually exclusive.

### BRIEF DESCRIPTION OF THE DRAWINGS

In the following preferred embodiments of the invention will be described, by way of example only, and with reference to the drawings in which:

FIG. 1 shows a flow chart which illustrates an example of a method;

FIG. 2 shows a flow chart which illustrates a further example of a method;

FIG. 3 illustrates an example of a medical apparatus;

FIG. 4 illustrates a further example of a medical apparatus;

FIG. 5 shows several images;

FIG. 6 shows several further images; and

FIG. 7 shows several further images.

### DETAILED DESCRIPTION OF THE EMBODIMENTS

Like numbered elements in these figures are either equivalent elements or perform the same function. Elements which have been discussed previously will not necessarily be discussed in later figures if the function is equivalent.

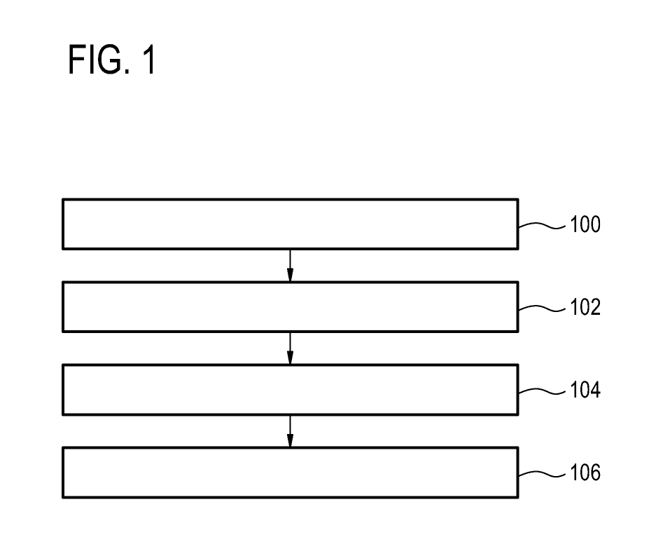

FIG. 1 shows a flowchart which illustrates an example of a method of generating a magnetic resonance image. First in step 100 a set of N magnetic resonance images is received. N is a positive integer greater than or equal to 1 or it is a positive integer greater than or equal to 2. Each of the set of N magnetic resonance images corresponds to one of N coil elements of a magnetic resonance imaging coil. Each of the set of N magnetic resonance images comprises the same number of pixels as the corrected magnetic resonance image. Next in step 102 a set of coil sensitivities is received for each of the N coil elements. Then in step 104 for each of the N coil elements a coil sensitivity calibration is determined for each of the pixels. Then in step 106 a value is calculated for each of the pixels of the corrected magnetic resonance image by dividing a first summation comprising the value of the pixel in each of the set of N magnetic resonance images by a second summation comprising the coil sensitivity for the pixel in each of the set of coil sensitivities. The first summation and the second summation are real valued. The corrected magnetic resonance image was generated in step 106 when the value for each of the pixels was calculated.

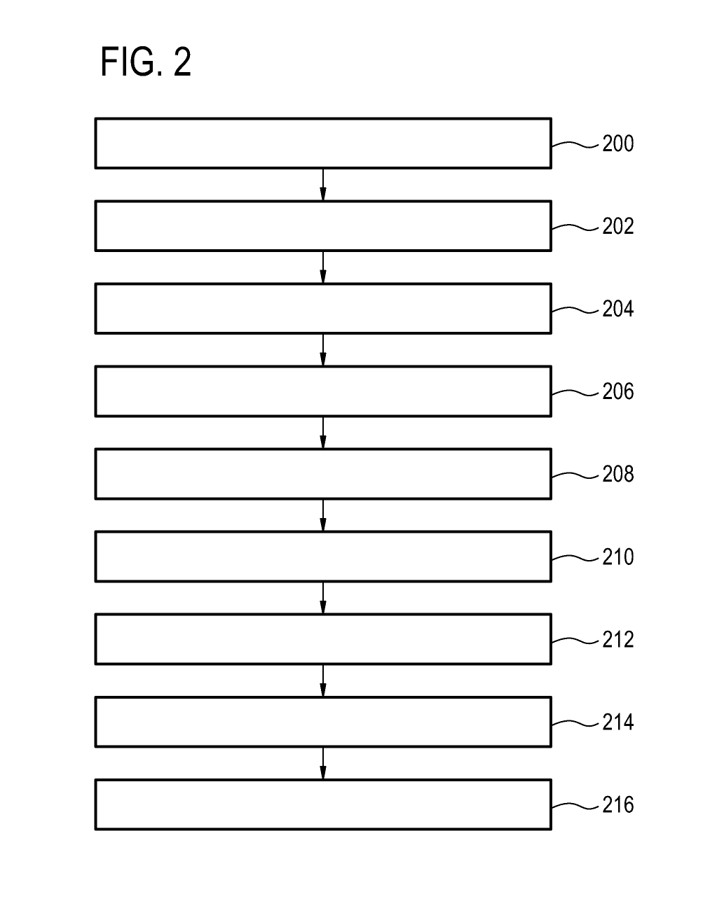

FIG. 2 shows a flowchart for a further method of producing or generating a corrected magnetic resonance image. The method is performed using a magnetic resonance imaging system which comprises a radio-frequency system operable for acquiring magnetic resonance data with the magnetic resonance imaging coil. The magnetic resonance imaging system further comprises a uniform body coil. The radio-frequency system is operable for acquiring reference magnetic resonance data using the uniform body coil. First in step 200 reference magnetic resonance data is acquired using the radio-frequency system and the uniform body coil. Next in step 202 a reference magnetic resonance image is reconstructed using the reference magnetic resonance data. Then in step 204 calibration magnetic resonance data is acquired using the radio-frequency system and the magnetic resonance imaging coil.

Next in step 206 a set of N calibration magnetic resonance images is reconstructed using the calibration magnetic resonance data. Then in step 208 the set of coil sensitivities are calculated using the set of N calibration magnetic resonance images and the reference magnetic resonance image. Next in step 210 imaging magnetic resonance data is acquired using the radio-frequency system and the magnetic resonance imaging coil. Then in step 212 the method comprises reconstructing the image magnetic resonance data into the set of N magnetic resonance images. Then in step 214 for each of the N coil elements a coil sensitivity calibration is determined for each of the pixels. Then finally in step 216 a value for each pixel of the pixels of the magnetic resonance image is calculated by dividing a first summation comprising the value of the pixel in each of the set of N magnetic resonance images by a second summation comprising the coil sensitivity calibrations for the pixel in each of the set of coil sensitivities. The first summation and the second summation are real valued.

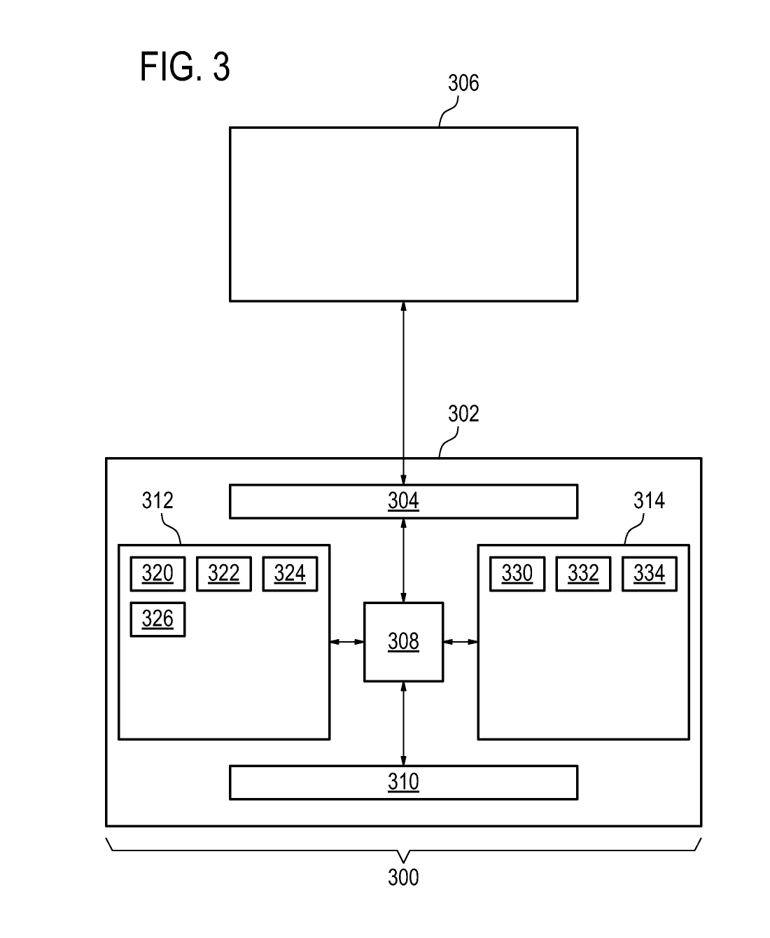

FIG. 3 shows a diagram which illustrates an example of a medical apparatus. The medical apparatus 300 is shown as comprising a computer 302. The computer 302 has an interface 304 which is connected to an external system 306. The external system 306 may for instance be a magnetic resonance imaging system or another data processing system. The computer 302 is further shown as containing a processor 308 which is operable for executing the machine-readable instructions. The computer 302 is further shown as comprising a user interface 310, computer storage 312 and computer memory 314 which are all accessible and connected to the processor 308. The computer storage 312 is shown as containing a set of N magnetic resonance images 320 that are received from the external system 306 via the interface 308. The computer storage 312 is further shown as containing a set of coil sensitivities 322 also received from the external system 306 via the interface 304. The computer storage 312 is further shown as containing a coil sensitivity calibration 324 that was calculated using the set of coil sensitivities 322. The computer storage 312 is further shown as containing a corrected magnetic resonance image 326 that was reconstructed or calculated using the set of N magnetic resonance images and the coil sensitivity calibrations 324.

The computer memory is shown as containing a control module 330. The control module 330 contains computer executable code which enables the processor 308 to perform calculations and to control the operation and function of the medical apparatus 300. For example in some cases the control module 330 may be used for controlling a magnetic resonance imaging system when the medical apparatus comprises a magnetic resonance imaging system. The computer memory 314 is further shown as containing a coil sensitivity calibration module 332. The coil sensitivity calibration module contains computer-executable code which enables the processor 308 to calculate the coil sensitivity calibration 324 from the set of coil sensitivities 322. The computer memory 314 is shown as further containing an image processing module 324. The image processing module 324 contains computer-executable code which enables the processor 308 to calculate the corrected magnetic resonance image using the coil sensitivity calibration and the set of N magnetic resonance images 320.

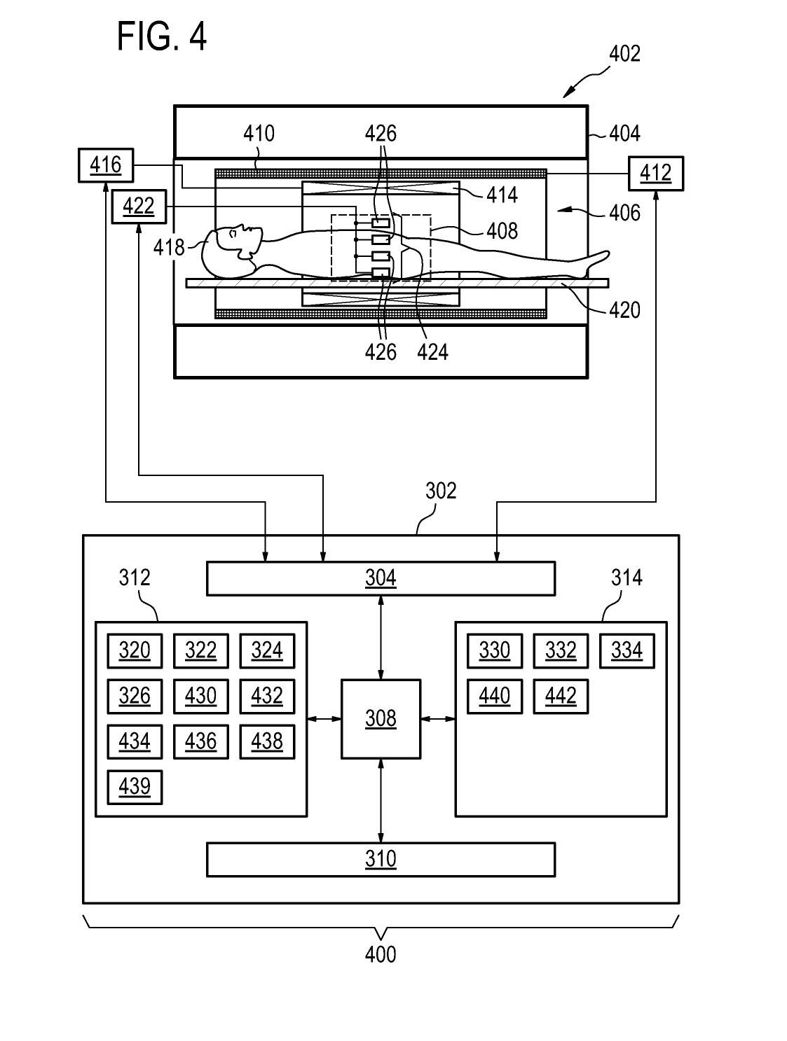

FIG. 4 shows a further example of a medical apparatus 400. The medical apparatus 400 comprises the computer system 302 of the example shown in FIG. 3. In this medical apparatus 400 the interface 304 is a hardware interface used for controlling a magnetic resonance imaging system 402. The medical apparatus is shown as further containing the magnetic resonance imaging system 402.

The medical apparatus 400 comprises a magnetic resonance imaging system 402 with a magnet 404. The magnet 404 is a superconducting cylindrical type magnet 404 with a bore 406 through it. The use of different types of magnets is also possible for instance it is also possible to use both a split cylindrical magnet and a so called open magnet. A split cylindrical magnet is similar to a standard cylindrical magnet, except that the cryostat has been split into two sections to allow access to the iso-plane of the magnet, such magnets may for instance be used in conjunction with charged particle beam therapy. An open magnet has two magnet sections, one above the other with a space in-between that is large enough to receive a subject: the arrangement of the two sections area similar to that of a Helmholtz coil. Open magnets are popular, because the subject is less confined. Inside the cryostat of the cylindrical magnet there is a collection of superconducting coils. Within the bore 406 of the cylindrical magnet 404 there is an imaging zone 408 where the magnetic field is strong and uniform enough to perform magnetic resonance imaging.

Within the bore 406 of the magnet there is also a set of magnetic field gradient coils 410 which is used for acquisition of magnetic resonance data to spatially encode magnetic spins within the imaging zone 408 of the magnet 404. The magnetic field gradient coils 410 connected to a magnetic field gradient coil power supply 412. The magnetic field gradient coils 410 are intended to be representative. Typically magnetic field gradient coils 110 contain three separate sets of coils for spatially encoding in three orthogonal spatial directions. A magnetic field gradient power supply supplies current to the magnetic field gradient coils. The current supplied to the magnetic field gradient coils 410 is controlled as a function of time and may be ramped or pulsed.

Within the bore 406 of the magnet 404 is a body coil 414. The body coil 414 is shown as being connected to a transceiver 416. In some embodiments body coil 414 may also be connected to a whole body coil radio frequency amplifier and/or receiver, however this is not shown in this example. If both a transmitter and a receiver 416 are connected to the whole body coil 414, a means for switching between the transmit and receive mode may be provided. For example a circuit with a pin diode may be used to select the transmit or receive mode. A subject support 420 supports a subject 418 within the imaging zone.

A transceiver 422 is shown as being connected to a magnetic resonance imaging coil 424. In this example the magnetic resonance imaging coil 424 is a surface coil comprising multiple coil elements 426. The transceiver 422 is operable for sending and receiving individual RF signals to the individual coil elements 426. In this example the transceiver 416 and the transceiver 422 are shown as being separate units. However, in other examples the units 416 and 422 could be combined.

The transceiver 416, the transceiver 422, and the magnetic field gradient coil power supply are shown as being connected to a hardware interface 304 of the computer 302. The computer storage 312 is further shown as containing pulse sequences 430. The pulse sequences 430 are sets of instructions which may be used by the processor 308 to control the magnetic resonance imaging system 402 to acquire magnetic resonance data. The computer storage is further shown as containing reference magnetic resonance data 432 that was acquired using the body coil 412 and the transceiver 416. The computer storage 312 is further shown as containing a reference magnetic resonance image 434 that was reconstructed from the reference magnetic resonance data 432. The computer storage 312 is further shown as containing calibration magnetic resonance data 436 that was acquired using the coil elements 426 and the transceiver 422. The computer storage is shown as further showing set of N calibration images 438 reconstructed from the calibration magnetic resonance data 436. The computer storage is shown as further containing imaging magnetic resonance data 439. The set of N magnetic resonance images 320 was reconstructed from the imaging magnetic resonance data 439. The imaging magnetic resonance data 439 was acquired using the magnetic resonance coil 424 and the transceiver 422.

The computer memory 314 is further shown as containing image reconstruction module 440. The image reconstruction module 440 contains computer-executable code which enables the processor 308 to reconstruct the reference magnetic resonance image 434 from the reference magnetic resonance data 432. The image reconstruction module 440 also enables the processor 308 to construct the set of N calibration resonance images 438 using the calibration magnetic resonance data 436. The computer memory 314 is further shown as containing a coil sensitivity calculation module 442. The coil sensitivity calibration module 442 contains code which enables the processor 308 to calculate the set of coil sensitivities 322 using the set of N calibration images 438 and the reference magnetic resonance image 434.

The method for reducing inhomogeneity of surface coils in magnetic resonance images as detailed in the '244 patent requires complex (real and imaginary) channel measurements and complex coil sensitivities as inputs. These requirements are, however, not compatible for sequences in which a large amount of phase information is removed in order to correct system imperfection. The PROPELLER method is a particular example.

As a workaround, for PROPELLER with local phase correction (Pipe phase correction), only root-mean-sum-of-squares is currently used in some commercial magnetic resonance imaging systems. This is not a desired solution as root-mean-sum-of-squares is known to be inferior to the method of the '244 patent. Hereafter, the method of the '244 patent is referred to as the CLEAR method. To address this, a new type of CLEAR method termed “pCLEAR” is detailed which enables CLEAR uniformity using only magnitude data and coil sensitivities.

This invention aims at enabling CLEAR uniformity for PROPELLER with local phase correction as detailed in Pipe et. al. pCLEAR is also applicable for all sequences that do not generate the complete phase information.

On one hand, CLEAR operation requires complex data and coil sensitivities as inputs; on the other hand, PROPELLER with local phase correction (being the most favorable PROPELLER technique due to its robustness to motion and system imperfection) removes a large amount of phase (cf. Pipe et. al.). The two techniques are therefore not compatible.

pCLEAR creates a CLEAR uniformity using only magnitude information of measured data and coil sensitivities. Therefore it is advantageous over normal CLEAR since the new technique does not depend on phase information.

pCLEAR is summarized as follows: Measurement in the i-th channel in image space: mᵢ=Sᵢ ρ, where Sᵢ is the complex coil sensitivity and ρ is the object.

pCLEAR reconstruction is then determined pixel by pixel as:

$${ρ}_{pCLEAR} = {\sum }_{i = 1}^{N} \vert {S}_{i} \vert \vert {m}_{i} \vert / ( {\sum }_{i = 1}^{N} ( {\vert {S}_{i} \vert}^{2} ) + {R}^{- 1} )$$

$$or$$

$${\sum }_{i = 1}^{N} \vert {S}_{i} \vert \vert {m}_{i} \vert / ( {\sum }_{i = 1}^{N} {\vert {S}_{i} \vert}^{2} )$$

$$or$$

$${\sum }_{i = 1}^{N} \vert {S}_{i} \vert \vert {m}_{i} \vert / ( ( {\sum }_{i = 1}^{N} {\vert {S}_{i} \vert}^{2} ) + {R}^{- 1} ) \\ or \\ {\sum }_{i = 1}^{N} \vert {S}_{i} \vert \vert {m}_{i} \vert / ( {\sum }_{i = 1}^{N} {\vert {S}_{i} \vert}^{2} )$$

where the coefficients and variables in these equations has been defined above.

To demonstrate the benefit of pCLEAR, it is compared it with normal CLEAR when the complete phase information is available. It can be readily proved that ρ_{pCLEAR} is the same as the magnitude of

$$CLEAR ( {ρ}_{clear} = \vert \frac{{\sum }_{i} {S}_{i}^{*} {m}_{i}}{{\sum }_{i} {S}_{i}^{*} {S}_{i}} \vert , * is conjugate operation )$$

when phase information is available in Sᵢ and mᵢ for the normal CLEAR in noise free situation. They are also virtually the same for reasonable SNR. pCLEAR can also be extended in a similar way as CLEAR, such as using quad body coil (QBC) data for regularization. An alternative formulation can be:

$${ρ}_{pCLEAR} = \sqrt{{\sum }_{i = 1}^{N} {\vert {m}_{i} \vert}^{2}} / \sqrt{( {\sum }_{i = 1}^{N} {\vert {S}_{i} \vert}^{2} ) + {R}^{- 1}}$$

$$or$$

$$\sqrt{{\sum }_{i = 1}^{N} {\vert {m}_{i} \vert}^{2}} / \sqrt{{\sum }_{i = 1}^{N} {\vert {S}_{i} \vert}^{2}}$$

where the coefficients and variables in these equations has been defined above.

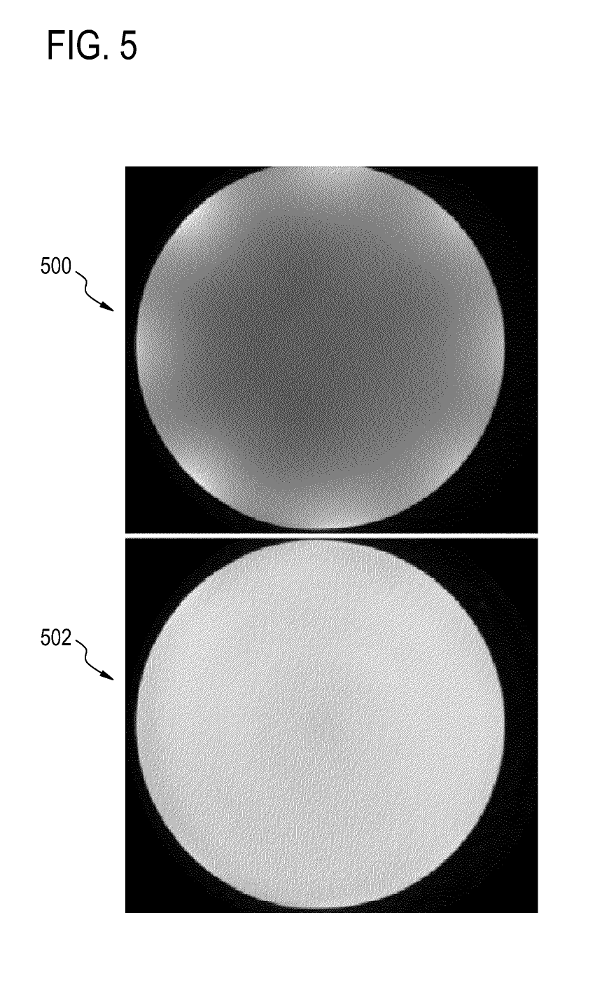

pCLEAR provides CLEAR like uniformity for PROPELLER with local phase correction. In practice, it can also be used for scans that do not generate complete phase information. Comparison studies of pCLEAR images and images processed normally without pCLEAR are shown in FIGS. 5, 6, and 7, showing improvements in phantom, brain, and spine.

FIG. 5 shows two images 500, 502. Image 500 shows a magnetic resonance image of a uniform phantom acquired with a multi-element surface coil. It can be observed that the center of the image is darker than the edges and there are numerous positions on the edge of the phantom where it is brighter. This is the position of individual coil elements. Image 502 shows the same data except when processed by an example of the pCLEAR method. FIG. 5 illustrates how the method can be used to make images more uniform. Both images 500, 502 are displayed in the same intensity range.

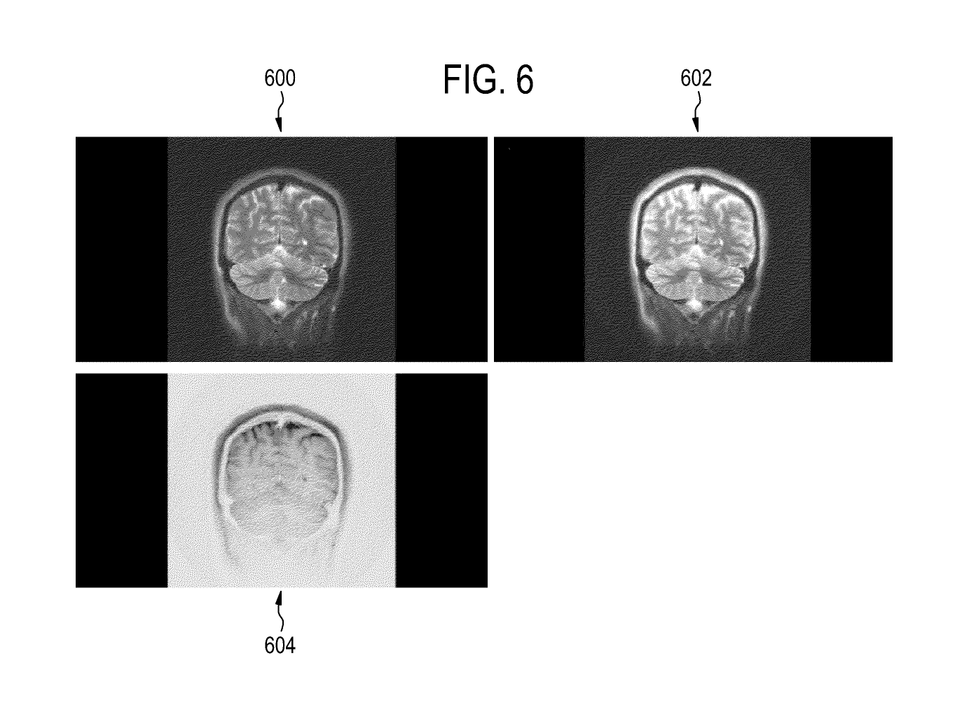

FIG. 6 shows three images 600, 602, 604. The image labeled 600 shows an image processed using an example of the pCLEAR method. Image 602 shows the same data but not processed with the pCLEAR method. It can be seen that the image is less uniform. In image 600 the brain surface is more uniform in contrast than in image 602. Image 604 shows the difference between images 600 and 602. Again, FIG. 6 illustrates the benefit of the method. Both images 600, 602 are displayed in the same intensity range.

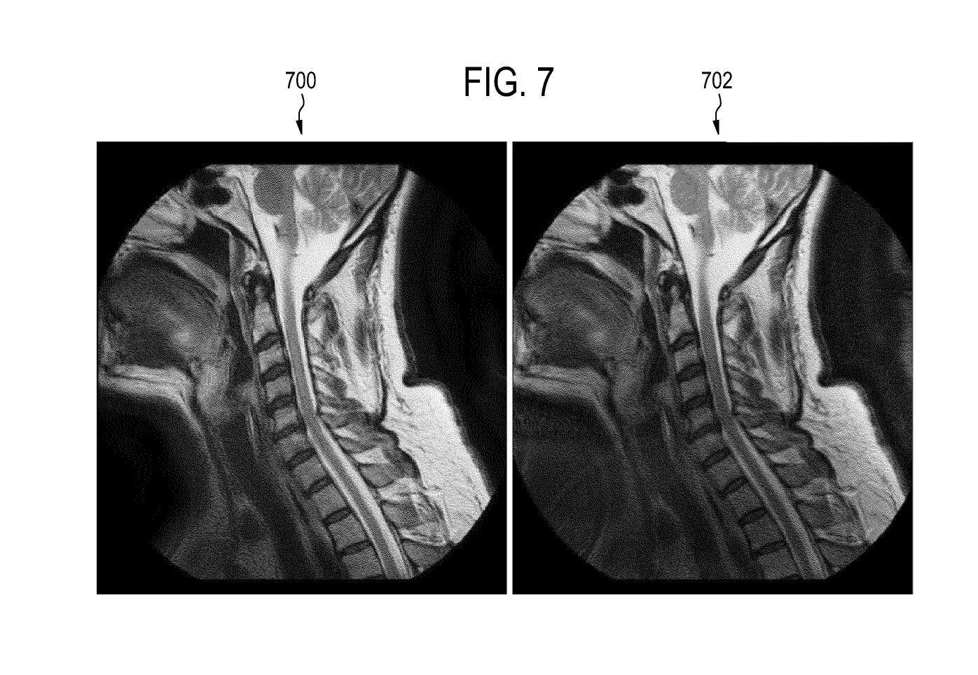

FIG. 7 shows two images 700, 702. Image 700 is a magnetic resonance image processed according to the pCLEAR method. Image 702 is an image processing the same data but not using the method. It can be seen that image 700 is much more uniform in contrast than image 702. FIG. 7 again illustrates the benefit of using the method. Both images 700, 702 are displayed in the same intensity range.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measured cannot be used to advantage. A computer program may be stored/distributed on a suitable medium, such as an optical storage medium or a solid-state medium supplied together with or as part of other hardware, but may also be distributed in other forms, such as via the Internet or other wired or wireless telecommunication systems. Any reference signs in the claims should not be construed as limiting the scope.

### LIST OF REFERENCE NUMERALS

300 medical apparatus
302 computer
304 interface
306 external system
308 processor
310 user interface
312 computer storage
314 computer memory
320 set of N magnetic resonance image
322 set of coil sensitivities
324 coil sensitivity calibration
326 corrected magnetic resonance image
330 control module
332 coil sensitivity calibration module
324 image processing module
400 medical apparatus
402 magnetic resonance imaging system
404 magnet
406 bore of magnet
408 imaging zone
410 magnetic field gradient coils
412 magnetic field gradient coil power supply
414 body coil
416 transceiver
418 subject
420 subject support
422 transceiver
424 magnetic resonance image coil
426 coil element
430 pulse sequences
432 reference magnetic resonance data
434 reference magnetic resonance image
436 calibration magnetic resonance data
438 set of N calibration images
439 image magnetic resonance data
440 image reconstruction module
442 coil sensitivity calculation module
500 image
502 corrected image
600 corrected image
602 image
604 image
700 corrected image
702 image

1. A medical apparatus for generating a corrected magnetic resonance image comprising pixels, wherein the medical apparatus comprises:
a memory for storing machine executable instructions; and
a processor for executing the machine executable instructions, wherein execution of the machine executable instructions causes the processor to:
receive a set of N magnetic resonance images, wherein N is a positive integer greater than or equal to one, wherein each of the set of N magnetic resonance images corresponds to one of N coil elements of a magnetic resonance imaging coil, wherein each of the set of N magnetic resonance images comprises the same number of pixels as the corrected magnetic resonance image;
receive a set of coil sensitivities for each of the N coil elements;
determine for each of the N coil elements a coil sensitivity calibration for each of the pixels;
calculate a value for each pixel of the pixels of the corrected magnetic resonance image by dividing a first summation comprising the modulus value of the coil sensitivity calibration for the pixel in each of the set of coil sensitivities and of the pixel-value in each of the set of N magnetic resonance images by a second summation comprising the squared modulus of the coil sensitivity calibration for the pixel in each of the set of coil sensitivities, for reducing the inhomogeneity of the corrected magnetic resonance image acquired using surface coils with multiple elements.

2. The medical apparatus of claim 1, wherein the first summation is the summation of the magnitude of the coil sensitivity for the pixel in each of the set of coil sensitivities times the magnitude of the pixel in each of the set of N magnetic resonance images, and wherein the second summation is the summation of the square of the magnitude of the coil sensitivity for the pixel.

3. The medical apparatus of claim 1, wherein the first summation divided by the second summation is algebraically equivalent to:
Σᵢ₌₁^{N}|Sᵢ∥mᵢ| . . . / . . . (Σᵢ₌₁^{N}(|Sᵢ|²)+R⁻¹) . . . , or
Σᵢ₌₁^{N}|Sᵢ∥mᵢ| . . . / . . . (Σᵢ₌₁^{N}(|Sᵢ|²) . . . , or
Σᵢ₌₁^{N}|Sᵢ|mᵢ . . . /(Σᵢ₌₁^{N}(|Sᵢ|²)+R⁻¹) . . . , or
Σᵢ₌₁^{N}|Sᵢ|mᵢ . . . / . . . (Σᵢ₌₁^{N}(|Sᵢ|²) . . . , ,
wherein i is an index variable, wherein mᵢ is the value of the pixel in the ith member of the set of N magnetic resonance images, wherein Sᵢ is the coil sensitivity calibration for pixel of the ith member the set of coil sensitivities, and wherein R . . . , is a regularization parameter.

4. A medical apparatus for generating a corrected magnetic resonance image comprising pixels, wherein the medical apparatus comprises:
a memory for storing machine executable; and
a processor for executing the machine executable instructions, wherein execution of the machine executable instructions causes the processor to:
receive a set of N magnetic resonance images, wherein N is a positive integer greater than or equal to one, wherein each of the set of N magnetic resonance images corresponds to one of N coil elements of a magnetic resonance imaging coil, wherein each of the set of N magnetic resonance images comprises the same number of pixels as the corrected magnetic resonance image;
receive a set of coil sensitivities for each of the N coil elements;
determine for each of the N coil elements a coil sensitivity calibration for each of the pixels;
calculate a value for each pixel of the pixels of the corrected magnetic resonance image by dividing a first summation comprising a square of the magnitude of the value of the pixel in each of the set of N magnetic resonance images, by a second summation comprising a square root of the summation of the square of the magnitude of the complex coil sensitivity for the pixel.

5. A medical apparatus for generating a corrected magnetic resonance image comprising pixels, wherein the medical apparatus comprises:
a memory for storing machine executable instructions; and
a processor for executing the machine executable instructions, wherein execution of the machine executable instructions causes the processor to:
receive a set of N magnetic resonance images, wherein N is a positive integer greater than or equal to one, wherein each of the set of N magnetic resonance images corresponds to one of N coil elements of a magnetic resonance imaging coil, wherein each of the set of N magnetic resonance images comprises the same number of pixels as the corrected magnetic resonance image;
receive a set of coil sensitivities for each of the N coil elements;
determine for each of the N coil elements a coil sensitivity calibration for each of the pixels;
calculate a value for each pixel of the pixels of the corrected magnetic resonance image by dividing a first summation divided by a second summation is algebraically equivalent to:
\sqrt{Σᵢ₌₁^{N}|mᵢ|²}/ . . . {square root over ((Σᵢ₌₁^{N}(|Sᵢ|²)+R⁻¹)} . . . or
\sqrt{Σᵢ₌₁^{N}|mᵢ|²}/ . . . {square root over ((Σᵢ₌₁^{N}(|Sᵢ|²)},
wherein i is an index variable, wherein mᵢ is the value of the pixel in the ith member of the set of N magnetic resonance images, wherein Sᵢ is the coil sensitivity calibration for pixel of the ith member the set of coil sensitivities, and wherein and wherein R is a regularization parameter.

6. The medical apparatus of claim 1, wherein execution of the instructions causes the processor to receive the coil sensitivities when the coil sensitivities are acquired in partial k-space.

7. The medical apparatus of claim 1, wherein the pixels in each of the set of N magnetic resonance images are real valued.

8. The medical apparatus of claim 1, wherein the medical apparatus comprises a magnetic resonance imaging system, wherein the magnetic resonance imaging system further comprises a radio frequency system operable for acquiring magnetic resonance data with the magnetic resonance imaging coil, wherein execution of the instructions further cause the processor to:
acquire imaging magnetic resonance data using the radio frequency system and the magnetic resonance imaging coil; and
reconstruct the imaging magnetic resonance data into the set of N magnetic resonance images.

9. The medical apparatus of claim 8, wherein the magnetic resonance imaging system further comprises a uniform body coil, wherein the radio frequency system is operable for acquiring reference magnetic resonance data using the uniform body coil, wherein execution of the instructions further cause the processor to:
acquire the reference magnetic resonance data using the radio frequency system and the uniform body coil,
acquire calibration magnetic resonance data using the using the radio frequency system and the magnetic resonance imaging coil;
reconstruct a reference magnetic resonance image using the reference magnetic resonance data;
reconstruct a set of N calibration magnetic resonance images using the calibration magnetic resonance data; and
calculate the set of coil sensitivities using the set of N calibration magnetic resonance images and the reference magnetic resonance image.

10. The medical apparatus of claim 8, wherein execution of the instructions cause the processor to acquire the imaging magnetic resonance data using a PROPELLER technique, and wherein the magnetic resonance data is reconstructed into the set of N magnetic resonance images using the PROPELLER technique.

11. The medical apparatus of claim 10, wherein the PROPELLER technique uses phase correction to remove a low-frequency spatially varying phase error in image space.

12. The medical apparatus of claim 8, wherein the imaging magnetic resonance data is acquired using a non-Cartesian magnetic resonance imaging technique.

13. A computer program product comprising machine executable instructions for execution by a processor controlling a medical apparatus, wherein execution of the machine executable instructions causes the processor to:
receive a set of N magnetic resonance images, wherein N is a positive integer greater than or equal to one, wherein each of the set of N magnetic resonance images corresponds to one of N coil elements of a magnetic resonance imaging coil, wherein each of the set of N magnetic resonance images comprises the same number of pixels as the corrected magnetic resonance image;
receive a set of coil sensitivities for each of the N coil elements;
determine for each of the N coil elements a coil sensitivity calibration for each of the pixels; and
calculate a value for each pixel of the pixels of the corrected magnetic resonance image by dividing a first summation comprising the modulus value of the pixel in each of the set of N magnetic resonance images by a second summation comprising the modulus of the coil sensitivity calibration for the pixel in each of the set of coil sensitivities.

14. A method of producing a corrected magnetic resonance image, wherein the method comprises the steps of:
receiving a set of N magnetic resonance images, wherein N is a positive integer greater than or equal to one, wherein each of the set of N magnetic resonance images corresponds to one of N coil elements of a magnetic resonance imaging coil, wherein each of the set of N magnetic resonance images comprises the same number of pixels as the corrected magnetic resonance image;
receiving a set of coil sensitivities for each of the N coil elements;
determining for each of the N coil elements a coil sensitivity calibration for each of the pixels; and
calculating a value for each pixel of the pixels of the corrected magnetic resonance image by dividing a first summation comprising the modulus value of the pixel in each of the set of N magnetic resonance images by a second summation comprising the modulus of the coil sensitivity calibration for the pixel in each of the set of coil sensitivities.

15. The method of claim 14, wherein the method is performed using a magnetic resonance imaging system which comprises a radio frequency system operable for acquiring magnetic resonance data with the magnetic resonance imaging coil, wherein the magnetic resonance imaging system further comprises a uniform body coil, wherein the radio frequency system is operable for acquiring reference magnetic resonance data using the uniform body coil, wherein the method further comprises the steps of:
acquiring the reference magnetic resonance data using the radio frequency system and the uniform body coil;
reconstructing a reference magnetic resonance image using the reference magnetic resonance data;
acquiring calibration magnetic resonance data using the using the radio frequency system and the magnetic resonance imaging coil;
reconstructing a set of N calibration magnetic resonance images using the calibration magnetic resonance data;
calculating the set of coil sensitivities using the set of N calibration magnetic resonance images and the reference magnetic resonance image;
acquiring imaging magnetic resonance data using the radio frequency system and the magnetic resonance imaging coil; and
reconstructing the imaging magnetic resonance data into the set of N magnetic resonance images.
